(19) United States
(12) Patent Application Publication
(10) Pub. No.: US 2006/0221749 A1
(43) Pub. Date: Oct. 5, 2006

(54) Internal voltage generating circuit

(75) Inventor: Ki-Chang Kwean, Kyoungki-do (KR)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(73) Assignee: Hynix Semiconductor Inc.

(21) Appl. No.: 11/322,299

(22) Filed: Dec. 29, 2005

(30) Foreign Application Priority Data
Mar. 31, 2005 (KR) 2005-0027402

(51) Int. Cl. G11C 5/14

(52) U.S. Cl. 365/226

(57) ABSTRACT

There is an internal voltage generating circuit for stably generating a core voltage of the semiconductor memory device under a low voltage circumstances. The internal voltage generating circuit includes a core voltage driving unit for generating a core voltage after a power is applied; and a low voltage mode driving unit for generating the core voltage when a level of a source voltage is lower than a target level of the core voltage, by detecting the level of the source voltage.

### FIELD OF THE INVENTION

The present invention relates to a semiconductor design technology; and, more particularly, to an internal voltage generating circuit for stably generating a core voltage of the semiconductor memory device under a low voltage circumstances.

### DESCRIPTION OF RELATED ART

Generally, as a semiconductor memory device is more integrated, a cell size in the semiconductor memory device is smaller. As a result, an operating voltage is also getting lower.

Most of the semiconductor memory devices include an internal voltage generating circuit which receives an external voltage VDD to generate various levels of an internal voltage. The internal voltage generating circuit supplies the internal voltage required to operate the semiconductor memory device in itself. A main issue to design the internal voltage generating circuit is to stably supply a relevant level of the internal voltage.

In case of the internal voltage generating circuit for generating a core voltage used for amplifying a cell data, the internal voltage generating circuit is composed of a voltage down converter.

FIG. 1 is a block diagram of a conventional core voltage generating circuit.

Referring to FIG. 1, the conventional core voltage generating circuit includes a core voltage driving unit for standby mode 10 and a core voltage driving unit for active mode 20.

The core voltage driving unit for standby mode 10 receives a reference voltage VREF to thereby continuously generate a core voltage VCORE when a power is applied. As a result, the core voltage driving unit for standby mode 10 stably maintains a level of the core voltage VCORE supply.

The core voltage driving unit for active mode 20 receives the reference voltage VREF and a chip active signal CHIP_ACT to thereby generate the core voltage VCORE when the chip active signal CHIP_ACT is activated, i.e., a semiconductor memory device enters an active mode.

The core voltage driving unit for active mode 20 has a driving power larger than that of the core voltage driving unit for standby mode 10.

FIG. 2 is a circuit diagram of a conventional core voltage driving unit implemented with a voltage down converter.

Referring to FIG. 2, the conventional core voltage driving unit includes a comparator 30 and a pull-up PMOS transistor M1.

The comparator 30 compares a level of a reference voltage VREF with a level of a core voltage VCORE which is feedbacked from an output node of the pull-up PMOS transistor M1.

The pull-up PMOS transistor M1 connected between a source voltage VDD supply and the core voltage VCORE supply has a gate receiving a driving control signal DRV_ONB outputted from the comparator 30.

It is more preferable that the comparator 30 is implemented as a differential amplifier having a current mirror type. The core voltage driving unit for standby mode 10 and the core voltage driving unit for active mode 20 of FIG. 1 have a structure of the voltage down converter in FIG. 2.

In case of the core voltage driving unit for active mode 20, the comparator 30 receives the chip active signal CHIP_ACT as well as the reference voltage VREF so that the chip active signal CHIP_ACT enables the comparator 30.

In the semiconductor memory device, if a bitline sense amplifier is operated, a core current is consumed. As a result, the core voltage VCORE is dropped. The comparator 30 compares the reference voltage VREF with the core voltage VCORE feedbacked from the output node of the pull-up PMOS transistor M1.

In case that the core voltage VCORE is lower than the reference voltage VREF, the driving control signal DRV_ONB is activated as a logic level ‘LOW’. Accordingly, the pull-up PMOS transistor M1 is turned on so as to pull up the core voltage VCORE with the source voltage VDD.

In case that the core voltage VCORE becomes higher than the reference voltage VREF, the driving control signal DRV_ONB is inactivated as a logic level ‘HIGH’. Accordingly, the pull-up PMOS transistor M1 is turned off so as not to supply an additional voltage to the core voltage VCORE.

FIG. 3 is a circuit diagram of another conventional core voltage driving unit implemented with a voltage down converter.

Referring to FIG. 3, the conventional core voltage driving unit includes a comparator 40, a pull-up PMOS transistor M2, a first resistor R1 and a second resistor R2.

The comparator 40 compares a level of a reference voltage VREF with a level of a core voltage VCORE feedbacked from a node connected between the first resistor R1 and the second resistor R2.

The pull-up PMOS transistor M2 connected between a source voltage VDD supply and the core voltage VCORE supply has a gate receiving a driving control signal DRV_ONB outputted from the comparator 40.

The first resistor R1 and the second resistor R2 are connected in series to thereby form a voltage divider. Generally, the first resistor R1 and the second resistor R2 have the same resistance. Hence, a comparison voltage VCOMP outputted from the voltage divider generally has the core voltage VCORE divided by 2.

The core voltage driving unit shown in FIG. 3 has the same operation of the core voltage driving unit shown in FIG. 2, except that the comparator 40 receives the comparison voltage VCOMP.

In the mean time, the conventional core voltage generating circuit has a problem related with a driving power under a low source voltage VDD circumstance. Namely, in case that a target level of the core voltage VCORE is 1.6 V, the core voltage VCORE is dramatically decreased in the region below 1.6 V.

This is because of a delay taken for enabling the core voltage driving unit for active mode 20. In other words, in case that the semiconductor memory device enters the active mode so that the core voltage generating circuit supplies the core voltage VCORE, the core voltage driving unit for active mode 20 should be rapidly operated.

However, because of a slow response speed under the low source voltage VDD circumstances, the core voltage driving unit for active mode 20 supplies the core voltage VCORE being fairly dropped. As a result, the core voltage VCORE is dropped much more than the target level of the core voltage VCORE.

As described above, the dropped core voltage VCORE under the low source voltage VDD circumstances appears to a noise so that the semiconductor memory device fails to operate.

### SUMMARY OF THE INVENTION

It is, therefore, an object of the present invention to provide an internal voltage generating circuit which can guarantee a driving power to thereby stably generate the core voltage of the semiconductor memory device under a low voltage circumstances.

In accordance with an aspect of the present invention, there is provided an internal voltage generating circuit including: a core voltage driving unit for generating a core voltage after a power is applied; and a low voltage mode driving unit for generating the core voltage when a level of a source voltage is lower than a target level of the core voltage, by detecting the level of the source voltage.

In accordance with another aspect of the present invention, there is provided a semiconductor memory device for stably generating a core voltage under a low voltage circumstances including: a core voltage driving unit for generating a core voltage after a power is applied; and a low voltage mode driving unit for generating the core voltage when a level of a source voltage is lower than a target level of the core voltage, by detecting the level of the source voltage.

### BRIEF DESCRIPTION OF THE DRAWINGS

The above and other objects and features of the present invention will become apparent from the following description of the preferred embodiments given in conjunction with the accompanying drawings, in which:

FIG. 1 is a block diagram of a conventional core voltage generating circuit;

FIG. 2 is a circuit diagram of a conventional core voltage driving unit;

FIG. 3 is a circuit diagram of another conventional core voltage driving unit;

FIG. 4 is a block diagram of a core voltage generating circuit in accordance with a first embodiment of the present invention;

FIG. 5 is a circuit diagram of a core voltage driving unit for low voltage mode shown in FIG. 4;

FIG. 6 is a waveform illustrating operating voltages of the core voltage generating circuit shown in FIG. 4;

FIG. 7 is a circuit diagram of a core voltage generating circuit in accordance with a second embodiment of the present invention; and

FIG. 8 is a circuit diagram of a core voltage generating circuit in accordance with a third embodiment of the present invention.

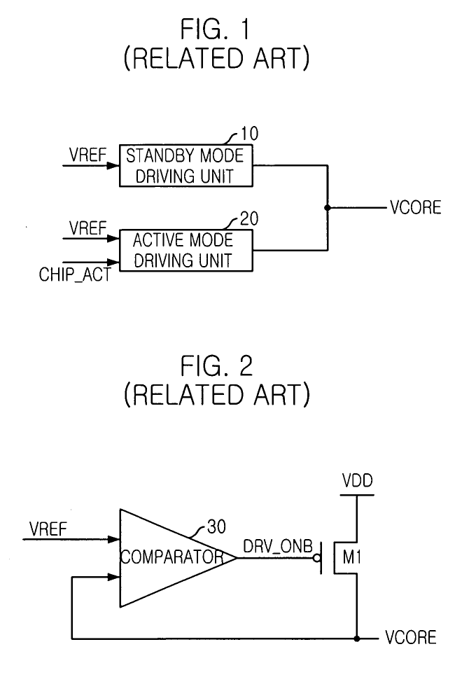

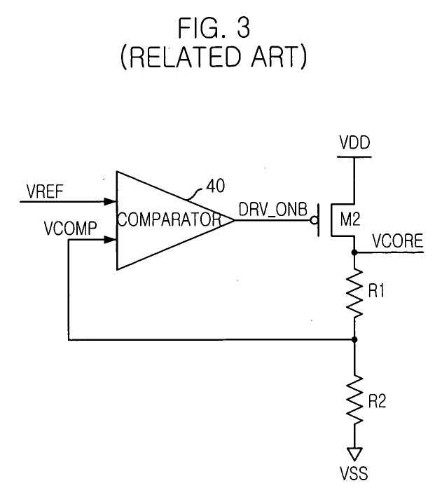

### DETAILED DESCRIPTION OF THE INVENTION

Other objects and aspects of the invention will become apparent from the following description of the embodiments with reference to the accompanying drawings, which is set forth hereinafter.

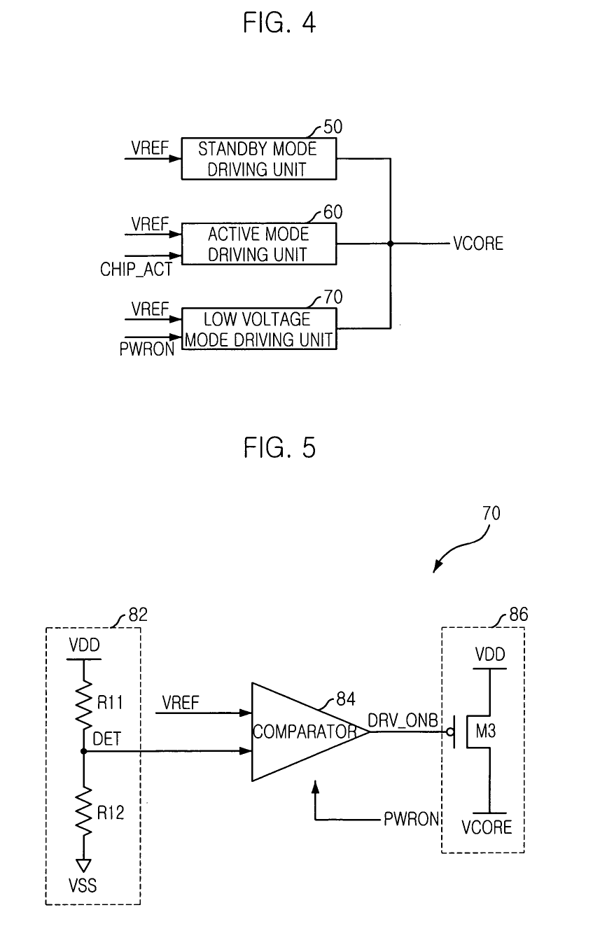

FIG. 4 is a block diagram of a core voltage generating circuit in accordance with a first embodiment of the present invention.

Referring to FIG. 4, the core voltage generating circuit includes a core voltage driving unit for standby mode 50, a core voltage driving unit for active mode 60 and a core voltage driving unit for low voltage mode 70.

The core voltage driving unit for standby mode 50 continuously generates a core voltage VCORE after a power is applied.

The core voltage driving unit for active mode 60 generates the core voltage VCORE when a chip active signal CHIP_ACT activated in an active mode is activated.

The core voltage driving unit for low voltage mode 70 generates the core voltage VCORE in response to a power-on signal PWRON when a level of a source voltage VDD is lower than a first target level of the core voltage VCORE, by detecting the level of the source voltage VDD.

Wherein, the core voltage driving unit for standby mode 50 has the same circuit configuration as that of the prior art.

FIG. 5 is a circuit diagram of the core voltage driving unit for low voltage mode 70 shown in FIG. 4.

Referring to FIG. 5, the core voltage driving unit for low voltage mode 70 includes a voltage level detect unit 82, a comparator 84 and a pull-up driving unit 86.

The voltage level detect unit 82 includes a voltage divider having a first resistor R11 and a second resistor R12 connected between the source voltage VDD supply and a ground voltage supply VSS in series to thereby detect the level of the source voltage VDD.

The comparator 84 compares a reference voltage VREF with an output node DET of the voltage level detect unit 82 to thereby output a driving control signal DRV_ONB according to the comparison result.

The pull-up driving unit 86 includes a pull-up PMOS transistor M3 which has a gate receiving the driving control signal DRV_ONB and is connected between the source voltage VDD supply and the core voltage VCORE supply to thereby pull up the core voltage VCORE with the source voltage VDD in response to the driving control signal DRV_ONB.

In case that the reference voltage VREF has a value of the core voltage VCORE divided by 2, the first resistor R11 and the second resistor R12 of the voltage divider may have the same resistance.

In case that the reference voltage VREF does not have the value of the core voltage VCORE divided by 2, the first resistor R11 and the second resistor R12 of the voltage divider may have a proper resistance in consideration of a sensing margin. The power-on signal PWRON activated when the power is applied is inputted to the comparator 84 to thereby enable the comparator 84.

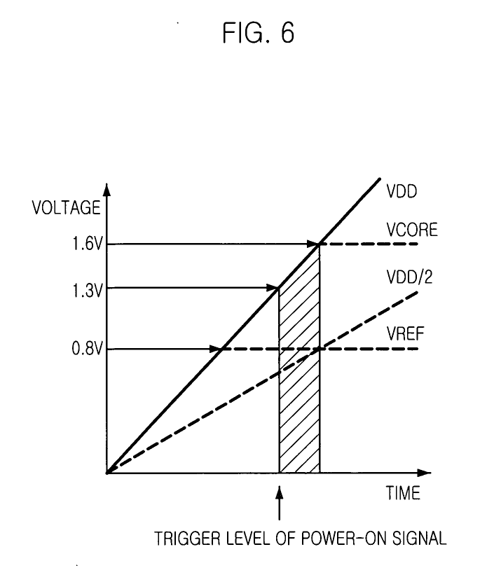

FIG. 6 is a waveform illustrating operating voltages of the core voltage generating circuit shown in FIG. 4.

Hereinafter, referring to FIG. 6, an operation of a core voltage generating circuit is described as follows.

To begin with, if the source voltage VDD is applied, the source voltage VDD is linearly rising up to a normal source voltage level. After the core voltage VCORE is rising up to a first target level according to a level of the source voltage VDD, the core voltage VCORE maintains the first target level.

After the reference voltage VREF is rising up to a second target level, the reference voltage VREF maintains the second target level. Herein, the first target level is about 1.6V and the second target level is about the core voltage VCORE divided by 2, i.e., 1.6/2=0.8V.

In the mean time, when the power is applied, the output node DET of the voltage level detect unit 82 in FIG. 5 is rising according to the source voltage VDD. So, the voltage level of the output node DET has a voltage level of the source voltage VDD divided by 2 to thereby show information about the level of the source voltage VDD.

In case that the voltage level of the output node DET is lower than the second target level of the reference voltage VREF, i.e., 0.8V, the comparator 80 of the core voltage driving unit for low voltage mode 70 outputs the driving control signal DRV_ONB having a logic level ‘LOW’. As a result, the pull-up PMOS transistor M3 is turned on.

In case that the voltage level of the output node DET is the second target level of the reference voltage VREF, i.e., 0.8V, the comparator 80 outputs the driving control signal DRV_ONB having a logic level ‘HIGH’. As a result, the pull-up PMOS transistor M3 is turned off.

In the mean time, the power-on signal PWRON is activated when the source voltage VDD is up to a trigger level after the power is applied. As a result, the comparator 80 is disabled until the power-on signal PWRON reaches the trigger level so as to be activated. Wherein, for example, the trigger level of the power-on signal PWRON is about 1.3V.

Accordingly, a section, which the pull-up PMOS transistor M3 of the core voltage driving unit for low voltage mode 70 is substantially turned on, is between the trigger level of the power-on signal PWRON and the first target level of the core voltage VCORE. Namely, the section is between 1.3V and 1.6V.

After all, the core voltage generating unit in the first embodiment of the present invention pulls up the core voltage VCORE with the source voltage VDD when the source voltage VDD is lower than the first target level after power is applied, i.e., the output node DET of the voltage level detect unit 82 is lower then the second target level. As a result, it is possible to stably generating the core voltage VCORE without dropping caused by a slow response speed under the low source voltage VDD circumstances.

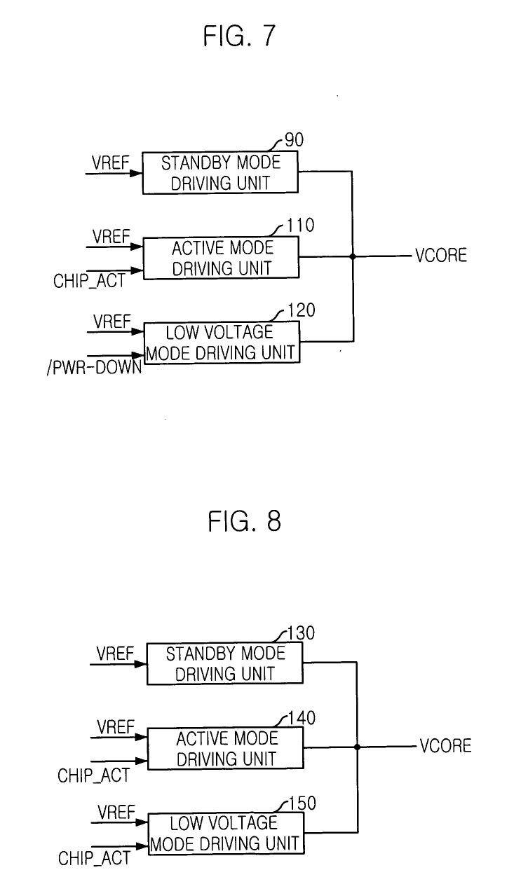

FIG. 7 is a circuit diagram of a core voltage generating circuit in accordance with a second embodiment of the present invention.

Referring to FIG. 7, the core voltage generating circuit in accordance with the second embodiment of the present invention includes a core voltage driving unit for standby mode 90, a core voltage driving unit for active mode 110 and a core voltage driving unit for low voltage mode 120.

The core voltage driving unit for standby mode 90 continuously generates a core voltage VCORE after a power is applied. The core voltage driving unit for active mode 110 generates the core voltage VCORE when a chip active signal CHIP_ACT activated in an active mode is activated. The core voltage driving unit for low voltage mode 120 generates the core voltage VCORE in response to a power-down bar signal /PWR-DOWN when a level of a source voltage VDD is lower than a target level of the core voltage VCORE, by detecting the level of the source voltage VDD.

A difference between the first embodiment and the second embodiment is that the power-down bar signal /PWR-DOWN is used for enabling the core voltage driving unit for low voltage mode 120. A power-down signal PWR-DOWN is activated in a logic level ‘HIGH’ when the semiconductor memory device enters a power-down mode or a self-refresh mode. The power-down bar signal /PWR-DOWN can be generated by inverting the power-down signal PWR-DOWN.

Accordingly, it is possible to disable the core voltage driving unit for low voltage mode 120 during a section which a current of the semiconductor memory device is rarely consumed. In general, a phenomenon that the core voltage VCORE is dropped under the low source voltage VDD circumstances is occurred in the active mode, so that it is easy to use the power-down bar signal /PWR-DOWN as an enable signal for enabling the core voltage driving unit for low voltage mode 120.

FIG. 8 is a circuit diagram of a core voltage generating circuit in accordance with a third embodiment of the present invention.

Referring to FIG. 8, the core voltage generating circuit in accordance with the third embodiment of the present invention includes a core voltage driving unit for standby mode 130, a core voltage driving unit for active mode 140 and a core voltage driving unit for low voltage mode 150.

The core voltage driving unit for standby mode 130 continuously generates a core voltage VCORE after a power is applied. The core voltage driving unit for active mode 140 generates the core voltage VCORE when a chip active signal CHIP_ACT activated in an active mode is activated. The core voltage driving unit for low voltage mode 150 generates the core voltage VCORE in response to the chip active signal CHIP_ACT when a level of a source voltage VDD is lower than a target level of the core voltage VCORE, by detecting the level of the source voltage VDD.

A difference between the third embodiment and the first or the second embodiment is that the chip active signal CHIP_ACT is used for enabling the core voltage driving unit for low voltage mode 150.

As described above, a phenomenon which the core voltage VCORE is dropped under the low source voltage VDD circumstances is occurred in the active mode, so that it is possible to enable the core voltage driving unit for low voltage mode 150 only for the active mode, by using the chip active signal CHIP_ACT.

In aforesaid embodiments, the pull-up PMOS transistor is taken as an example of a core voltage driver. It is possible to be substituted by other driving means.

Besides, in the aforesaid embodiments, the low voltage driving unit is explained in case that the core voltage is directly feedbacked. It is possible to change a feedback method such that the core voltage is feedbacked after being divided.

In the aforesaid embodiments, a level of the core voltage divided by 2 is taken as an example of the reference voltage VREF. It is possible to use a level of the core voltage as the reference voltage VREF.

Also, in the aforesaid embodiments, the voltage divider is taken as an example of a level follower for detecting the level of the source voltage VDD. It is possible to use other types of voltage level detect means.

As described above, the low voltage driving unit of the core voltage generating unit in the present invention can guarantee a driving power to thereby stably generate the core voltage of the semiconductor memory device under the low voltage circumstances. As a result, it is possible to improve an operation characteristic of the semiconductor memory device and guarantees a reliance of the semiconductor memory device.

The present application contains subject matter related to Korean patent application No. 2005-27402, filed in the Korean Intellectual Property Office on Mar. 31, 2005, the entire contents of which is incorporated herein by reference.

While the present invention has been described with respect to certain preferred embodiments, it will be apparent to those skilled in the art that various changes and modifications may be made without departing from the scope of the invention as defined in the following claims.

What is claimed is:

1. An internal voltage generating circuit for generating a core voltage of a semiconductor memory device under a low voltage circumstances, comprising:
a core voltage driving unit for generating a core voltage after a power is applied; and
a low voltage mode driving unit for generating the core voltage when a level of a source voltage is lower than a target level of the core voltage, by detecting the level of the source voltage.

2. The internal voltage generating circuit as recited in claim 1, wherein the core voltage driving unit includes:
a standby mode driving unit for continuously generating the core voltage after a power is applied; and
an active mode driving unit for generating the core voltage when a chip active signal activated in an active mode is activated.

3. The internal voltage generating circuit as recited in claim 2, wherein the low voltage mode driving unit includes:
a voltage level detect unit for detecting the level of the source voltage; and
a comparison unit for comparing a reference voltage with an output of the voltage level detect unit to thereby output a driving control signal according to the comparison result; and
a pull-up driving unit for pulling up the core voltage with the source voltage in response to the driving control signal.

4. The internal voltage generating circuit as recited in claim 3, wherein the voltage level detect unit includes a voltage divider having a first resistor and a second resistor connected in series between the source voltage supply and a ground voltage supply.

5. The internal voltage generating circuit as recited in claim 4, wherein the reference voltage has the target level of the core voltage divided by 2.

6. The internal voltage generating circuit as recited in claim 5, wherein the first resistor and the second resistor have the same resistance.

7. The internal voltage generating circuit as recited in claim 3, wherein the pull-up driving unit includes a PMOS transistor which has a gate receiving the driving control signal and is connected between the source voltage supply and the core voltage supply.

8. The internal voltage generating circuit as recited in claim 7, wherein a power-on signal, which is activated when the source voltage is up to a predetermined level after the power is applied, is used for enabling the comparison unit.

9. The internal voltage generating circuit as recited in claim 7, wherein a power-down signal, which is activated in a power-down mode or a self-refresh mode, is used for enabling the comparison unit.

10. The internal voltage generating circuit as recited in claim 7, wherein the chip active signal, which is activated in the active mode, is used for enabling the comparison unit.

11. A semiconductor memory device for generating a core voltage of a semiconductor memory device under a low voltage circumstances, comprising:
a core voltage driving unit for generating a core voltage after a power is applied; and
a low voltage mode driving unit for generating the core voltage when a level of a source voltage is lower than a target level of the core voltage, by detecting the level of the source voltage.

12. The device as recited in claim 11, wherein the core voltage driving unit includes:
a standby mode driving unit for continuously generating the core voltage after a power is applied; and
an active mode driving unit for generating the core voltage when a chip active signal activated in an active mode is activated.

13. The device as recited in claim 12, wherein the low voltage mode driving unit includes:
a voltage level detect unit for detecting the level of the source voltage; and
a comparison unit for comparing a reference voltage with an output of the voltage level detect unit to thereby output a driving control signal according to the comparison result; and
a pull-up driving unit for pulling up the core voltage with the source voltage in response to the driving control signal.

14. The device as recited in claim 13, wherein the voltage level detect unit includes a voltage divider having a first resistor and a second resistor connected in series between the source voltage supply and a ground voltage supply.

15. The device as recited in claim 14, wherein the reference voltage has the target level of the core voltage divided by 2.

16. The device as recited in claim 15, wherein the first resistor and the second resistor have the same resistance.

17. The device as recited in claim 13, wherein the pull-up driving unit includes a PMOS transistor which has a gate receiving the driving control signal and is connected between the source voltage supply and the core voltage supply.

18. The device as recited in claim 17, wherein a power-on signal, which is activated when the source voltage is up to a predetermined level after the power is applied, is used for enabling the comparison unit.

19. The device as recited in claim 17, wherein a power-down signal, which is activated in a power-down mode or a self-refresh mode, is used for enabling the comparison unit.

20. The device as recited in claim 17, wherein the chip active signal, which is activated in the active mode, is used for enabling the comparison unit.
